(19) United States
(12) Patent Application Publication
(10) Pub. No.: US 2019/0348304 A1
(43) Pub. Date: Nov. 14, 2019

(54) CLEANING APPARATUS AND METHOD FOR CHIP-STACKED STRUCTURE

(71) Applicant: GRAND PLASTIC TECHNOLOGY CORPORATION, Hsinchu City (TW)

(72) Inventors: Fu-Yuan HUANG, Hsinchu City (TW); Zong-En WU, Hsinchu City (TW); Chih-Cheng WANG, Hsinchu City (TW)

(21) Appl. No.: 16/044,517

(22) Filed: Jul. 25, 2018

(30) Foreign Application Priority Data
May 10, 2018 (TW) 107115989

(51) Int. Cl. H01L 21/67; B08B 3/14; H01L 21/02

(52) U.S. Cl. CPC H01L 21/6704; H01L 21/02057; B08B 3/14

(57) ABSTRACT

A cleaning apparatus for removing residues from a chip stacked structure includes a platform on which the chip stacked structure is placed. A liquid supply device is for applying a cleaning liquid to the chip stacked structure to flow into a gap between chips and a substrate from a first side of the gap. A liquid suction device has a flexible skirt for engaging with the chips and is for providing a negative pressure to extract the cleaning liquid located in the gap through a second side of the gap, thereby bringing out the residues. A precise driving device is connected with the liquid suction device and has a vertical lifting mechanism for controlling the liquid suction device to move along a vertical direction, and a horizontal moving mechanism for controlling the liquid suction device to move along a horizontal direction.

### FIELD OF DISCLOSURE

The present disclosure relates to a cleaning apparatus and method, and more particularly to a cleaning apparatus and method for removing residues from a chip stacked structure.

### BACKGROUND

A general three-dimensional integrated circuit packaging process includes four steps: via formation, via filling, wafer thinning, and wafer bonding. A rinsing step must be performed before and after each of the four processing steps to avoid contamination of the wafer during processing thereof. Furthermore, the step of wafer bonding can be roughly divided into three types: chip to wafer (C2W), chip to chip (C2C), and wafer to wafer (W2W). However, a gap either formed between the wafers or formed between the wafer and the chip is usually 20 to 50 μm. Therefore, how to remove the residues in such a tiny gap is a technical bottleneck and challenge that urgently need to be overcome.

Taiwan Patent Publication No. TW 1539515 has disclosed a cleaning method of chip stacked structure and cleaning apparatus that can remove a flux or other impurities in a tiny gap between a wafer and a chip. However, in this patent publication, a roller-type or a brush-type sliding structure is provided at a bottom of a liquid suction device, so that the liquid suction device can slide on the substrate by the sliding structure to move to a cleaning position. That is, since the liquid suction device is moved in a horizontal direction on the chip stacked structure, when the liquid suction device moves to a relatively high location of the chip stack structure (for example, where there are more layers, or where the chip height is relatively high), an additional lateral impact force will be exerted to this relatively high location by the liquid suction device. Also, a downforce exerted by the liquid suction device at this relatively high location of the chip is also relatively large, resulting in chip damage.

Moreover, in the above-mentioned patent publication, the bottom of the liquid suction device is a roller-type or brush-type sliding structure; that is, there is a certain gap between rollers or between the bristles of the brush. Therefore, when the liquid suction device is in operation, gas and liquid drawn from the inside of the chip stacked structure are easily dissipated to the outside through the gaps between the rollers or the bristles of the brush, and cannot be completely drawn into a discharge pipe of the liquid suction device. On the other hand, because there are the gaps between the rollers or bristles of the brush, when the liquid suction device is in operation, extra gas is easily drawn in through the gaps, resulting in the necessity of enhancing an extraction force of the liquid suction device to ensure that the residuals in the tiny gaps of the chip stacked structure can be extracted, whereby a loading on a power source of the liquid suction device must be further increased.

Accordingly, it is necessary to provide a cleaning apparatus and method to solve the technical problem in the prior art.

### SUMMARY OF DISCLOSURE

In order to solve technical problems mentioned above, an object of the present disclosure is to provide a cleaning apparatus and method. By setting a moving mechanism in the cleaning apparatus to accurately control the position of the liquid suction device, excessive downforce applied on the chip stacked structure is avoided. Furthermore, by providing a flexible skirt at the bottom of the liquid suction device, it can avoid damage to the chip stacked structure and leakage of gas or liquid.

In order to achieve the objects described above, the technical solution provides a cleaning apparatus for removing residues from a chip stacked structure, the chip stacked structure including a substrate and a plurality of chips, the chips being separated from the substrate by a gap, and the residues located in the gap between the chips and the substrate, the cleaning apparatus including: a platform for placing the chip stacked structure thereon; a liquid supply device for applying a cleaning liquid to the substrate of the chip stacked structure so that the cleaning liquid flows into the gap from a first side of the gap; and a liquid suction device for providing a negative pressure to extract the cleaning liquid located in the gap through a second side of the gap, thereby bringing out the residues, where the liquid suction device including: a suction outlet; and a flexible skirt circumferentially disposed around the suction outlet and configured for contacting the chip stacked structure and blocking the cleaning liquid and gas therein from escaping through the second side of the gap so that the cleaning liquid and the gas will be ensured to be extracted through the suction outlet.

In one preferable embodiment of the present disclosure, a material of the flexible skirt includes a polyvinyl alcohol sponge.

In one preferable embodiment of the present disclosure, the cleaning apparatus further includes a precise driving device used for controlling the liquid suction device to move along a vertical direction and a horizontal direction with respect to the platform.

In one preferable embodiment of the present disclosure, the precise driving device includes a vertical lifting mechanism for controlling the liquid suction device to move along the vertical direction with respect to the platform, and the vertical lifting mechanism includes a stepper motor.

In one preferable embodiment of the present disclosure, the precise driving device includes a horizontal moving mechanism for controlling the liquid suction device to move along the horizontal direction with respect to the platform, and the horizontal moving mechanism includes an X-Y table.

In one preferable embodiment of the present disclosure, the horizontal moving mechanism can also be used to control a horizontal movement of the liquid supply device.

In one preferable embodiment of the present disclosure, the cleaning apparatus further includes a load cell, one end of the load cell contacts to the liquid suction device to detect a pressure value of the liquid suction device applied to the chip stacked structure.

In one preferable embodiment of the present disclosure, the cleaning apparatus further includes a gas-liquid separation device connected to the liquid suction device for separating the cleaning liquid and the gas which are extracted through the suction outlet.

In one preferable embodiment of the present disclosure, the cleaning apparatus further includes a negative pressure sensor connected to the liquid suction device for detecting a negative pressure value between the liquid suction device and the chip stacked structure when the flexible skirt of the liquid suction device contacts the chip stacked structure.

The present disclosure also provides a cleaning apparatus for removing residues from a chip stacked structure, the chip stacked structure including a substrate and a plurality of chips, the chips being separated from the substrate by a gap, and the residues located in the gap between the chips and the substrate, the cleaning apparatus including: a platform for placing the chip stacked structure thereon; a liquid supply device for applying a cleaning liquid to the substrate of the chip stacked structure so that the cleaning liquid flows into the gap from a first side of the gap; a liquid suction device for providing a negative pressure to extract the cleaning liquid located in the gap through a second side of the gap, thereby bringing out the residues; and a precise driving device for controlling the liquid suction device to move along a vertical direction and a horizontal direction with respect to the platform, where the precise driving device including: a vertical lifting mechanism for controlling the liquid suction device to move along the vertical direction with respect to the platform, and the vertical lifting mechanism includes a stepper motor; and a horizontal moving mechanism for controlling the liquid suction device to move along the horizontal direction with respect to the platform, and the horizontal moving mechanism includes an X-Y table.

In one preferable embodiment of the present disclosure, the horizontal moving mechanism can also be used to control a horizontal movement of the liquid supply device.

In one preferable embodiment of the present disclosure, the liquid suction device includes: a suction outlet; and a flexible skirt circumferentially disposed around the suction outlet and configured for contacting the chip stacked structure and blocking the cleaning liquid and gas therein from escaping through the second side of the gap so that the cleaning liquid and the gas will be ensured to be extracted through the suction outlet.

The present disclosure also provides a cleaning method, performed by a cleaning apparatus which includes a platform, a liquid supply device, a liquid suction device, and a precise driving device, and the cleaning method used for removing residues from a chip stacked structure, the chip stacked structure including a substrate and a plurality of chips, the chips being separated from the substrate by a gap, and the residues located in the gap between the chips and the substrate, the cleaning method including: placing the chip stacked structure on the platform; controlling the liquid suction device to move towards the chip stacked structure by a vertical lifting mechanism of the precise driving device, so that a flexible skirt of the liquid suction devices contacts the chip stacked structure; applying the cleaning liquid to the substrate of the chip stacked structure by the liquid supply device so that the cleaning liquid flows into the gap from a first side of the gap; and providing a negative pressure by the liquid suction device to extract the cleaning liquid located in the gap through a second side of the gap, thereby bringing out the residues.

In one preferable embodiment of the present disclosure, after the liquid suction device is controlled to move towards the chip stacked structure by the precise driving device, the method further includes: detecting a pressure value of the liquid suction device applied to the chip stacked structure by a load cell.

In one preferable embodiment of the present disclosure, when a negative pressure is provided by the liquid suction device, the method further includes: detecting a negative pressure value between the liquid suction device and the chip stacked structure by a negative pressure sensor when the flexible skirt of the liquid suction device contacts the chip stacked structure.

In one preferable embodiment of the present disclosure, after the chip stacked structure is placed on the platform, the method further includes: controlling a horizontal movement of the liquid supply device and the liquid suction device over the platform by a horizontal moving mechanism of a precise driving device to align the liquid supply device with the first side of the gap and align the liquid suction device with the second side of the gap.

In one preferable embodiment of the present disclosure, after the negative pressure is provided by the liquid suction device to extract the cleaning liquid, the gas, and the residues, the method further includes: separating the cleaning liquid and the gas which are extracted through the suction outlet by a gas-liquid separation device.

In comparison to prior art, the present disclosure provides a vertical lifting mechanism in the cleaning apparatus to accurately control a relative position between the liquid suction device and the chip stacked structure, so that it can avoid the problem caused from the liquid suction device applies an improper downforce on the chip stacked structure, thereby causing chips damage. Moreover, by providing a flexible skirt at the bottom of the liquid suction device, the flexible skirt can contact with the chip stacked structure and circumferentially cover a range of chip stacked structures to avoid leakage of gas or liquid.

### BRIEF DESCRIPTION OF DRAWINGS

FIG. 1 shows a schematic diagram of a cleaning apparatus according to a first preferred embodiment of the present disclosure.

FIG. 2 shows a block diagram of a moving mechanism of the cleaning apparatus of FIG. 1.

FIG. 3 shows a flow chart of a cleaning method according to a preferred embodiment of the present disclosure.

FIG. 4 shows a schematic diagram of a cleaning apparatus according to a second preferred embodiment of the present disclosure.

FIG. 5 shows a schematic diagram of a cleaning apparatus according to a third preferred embodiment of the present disclosure.

### DETAILED DESCRIPTION

The structure and the technical means adopted by the present disclosure to achieve the above and other objects can be best understood by referring to the following detailed description of the preferred embodiments and the accompanying drawings.

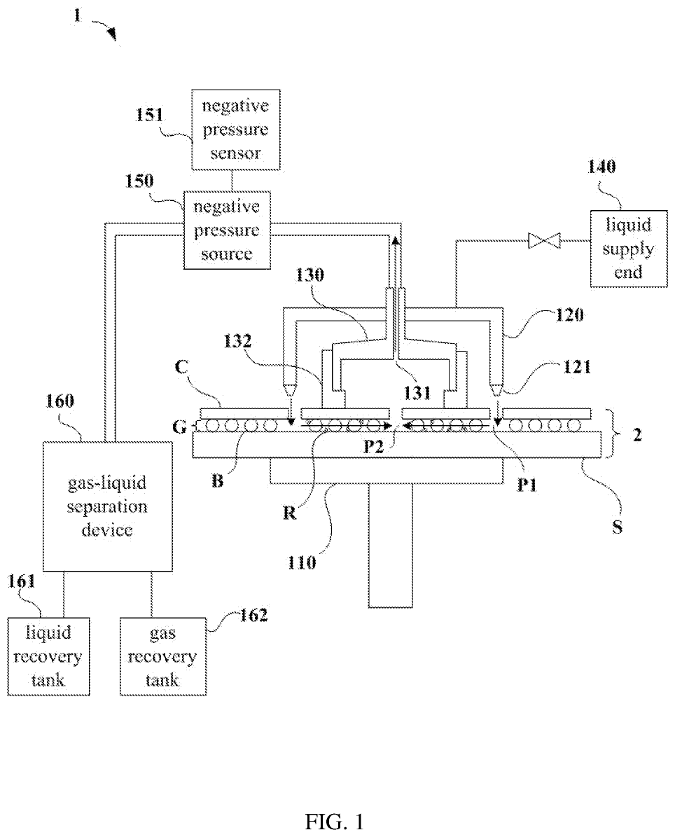

Referring to FIG. 1, which shows a schematic diagram of a cleaning apparatus according to a first preferred embodiment of the present disclosure. The cleaning apparatus 1 is used for removing residues on the chip stacked structure 2. The chip stacked structure 2 is a three-dimensional integrated circuit board that includes a substrate S and a plurality of chips C arranged in an array. A plurality of connection members B are provided between the chips C and the substrate S. The connection member B can be a solder ball that solders the substrate S and chips C or any suitable element. The connection member B is used to connect the substrate S and the chips C such that the substrate S and the chips C are separated by a gap G. The substance to be removed by the cleaning apparatus 1 is the residues R that are located in the gap G between the substrate S and the chips C.

As shown in FIG. 1, the cleaning apparatus 1 mainly includes a platform 110, a liquid supply device 120, and a liquid suction device 130. The platform 110 is used for placing the chip stacked structure 2 thereon. The liquid supply device 120 is movably disposed above the platform 110 for applying a cleaning liquid to the substrate S of the chip stacked structure 2, so that the cleaning liquid flows into the gap from a first side P1 of the gap G of the chip stacked structure 2. The liquid suction device 130 is movably disposed above the platform 110 for providing a negative pressure to extract the cleaning liquid located in the gap G through a second side P2 of the gap G (an arrow in FIG. 1 indicates the direction of the flow of the cleaning liquid), thereby bring out the residues R together.

As shown in FIG. 1, the liquid supply device 120 is connected to a liquid supply end 140 via a liquid supply pipe, where the liquid supply end 140 includes a tank for storing the cleaning liquid and a power source for driving liquid to flow, and the like. In addition, at least one valve is provided on the liquid supply pipe, and a circulation of the cleaning liquid is controlled by turning the valve on or off. In addition, a liquid outlet 121 is provided near an end of the platform 110 of the liquid supply device 120. In the present embodiment, the number of the liquid outlets 121 is two, and the positions thereof correspond to the opposite ends of two adjacent chips C. However, in other embodiments, a different number of liquid outlets 121 may be provided, not limited thereto.

As shown in FIG. 1, the liquid suction device 130 includes a suction outlet 131 and a flexible skirt 132. The suction outlet 131 of the liquid suction device 130 is connected to the negative pressure source 150 (e.g., an aspirator) through a withdrawal pipe. The operation of the negative pressure source 150 enables the liquid suction device 130 to generate a negative pressure, thereby extracting the cleaning liquid, the gas, and the residues R together. The flexible skirt 132 is a hollow annular wall, and the annular wall extends in a vertical direction and is circumferentially disposed around the suction outlet 131. The liquid suction device 130 is in contact with the chip stacked structure 2 by the flexible skirt 132. In the present disclosure, the flexible skirt 132 is made of a soft, dense material, such as a polyvinyl alcohol (PVA) sponge. Therefore, when the liquid suction device 130 and the chip stacked structure 2 are in contact, the flexible skirt 132 can prevent the chip C from being damaged due to the excessive pressure applied to the chip C through a soft buffering property of the flexible skirt 132. On the other hand, since the annular wall of the flexible skirt 132 does not have a gap that is clearly visible to the naked eye, when the liquid suction device 130 is in operation, gas and liquid drawn from the inside of the chip stacked structure 2 will not escape to the outside through the annular wall of the flexible skirt 132, but can be reliably pumped into the suction outlet 131 of the liquid suction device 130. Also, when the liquid suction device 130 is in operation, the external gas is not drawn in via the annular wall of the flexible skirt 132, so a loading on the negative pressure source 150 of the liquid suction device can be decreased.

As shown in FIG. 1, the cleaning apparatus 1 also includes a negative pressure sensor 151. The negative pressure sensor 151 is connected to the liquid suction device 130 through the negative pressure source 150 to detect a negative pressure value between the liquid suction device 130 and the chip stacked structure 2 when the flexible skirt 132 of the liquid suction device 130 contacts the chip stacked structure 2. Therefore, an operator can adjust the extraction force of the negative pressure source 150 according to the magnitude of the negative pressure value so as to avoid damage to the chip stacked structure 2.

As shown in FIG. 1, the cleaning apparatus 1 also includes a gas-liquid separation device 160. The gas-liquid separation device 160 is connected with the liquid suction device 130 for separating the cleaning liquid and gas extracted through the suction outlet 131 of the liquid suction device 130. Preferably, the gas-liquid separation device 160 is provided with a filter which can filter the extracted solid residues R, then separate the cleaning liquid from the gas, the cleaning liquid is finally introduced into the liquid recovery tank 161, and introduced the gas into the gas recovery tank 162. Therefore, the liquid and gas recovered after gas-liquid separation can be used after appropriate treatment. In addition, a flow meter can be installed in the liquid recovery tank 161 to record the pumping flow value.

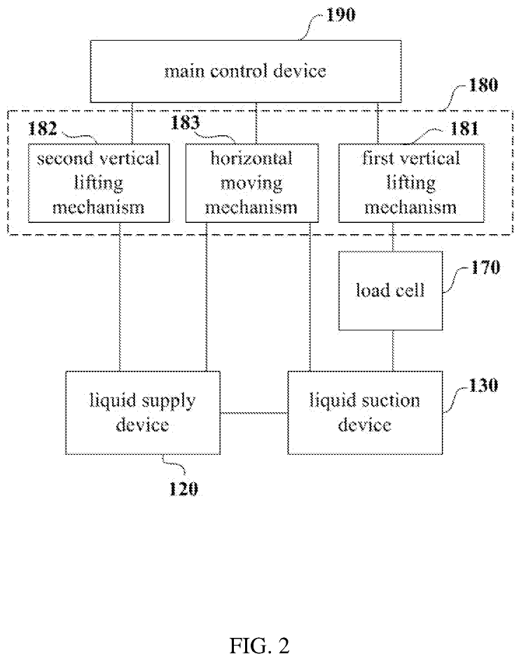

Referring to FIG. 2, which shows a block diagram of a moving mechanism of the cleaning apparatus of FIG. 1. The movement mechanism of the cleaning apparatus 1 includes a precise driving device 180 having a first vertical lifting mechanism 181, a second vertical lifting mechanism 182, and a horizontal moving mechanism 183. The first vertical lifting mechanism 181, the second vertical lifting mechanism 182, and the horizontal moving mechanism 183 of the precise driving device 180 are electrically connected to a main control device 190 (e.g., a computer), such that the operation of the moving mechanism of the cleaning apparatus 1 can be set by a control program in the main control device 190.

As shown in FIG. 2, the first vertical lifting mechanism 181 is connected to the liquid suction device 130, and the second vertical lifting mechanism 182 is connected to the liquid supply device 120. The first vertical lifting mechanism 181 has a connection member connected to the liquid suction device 130 and a precise driving element (such as a stepper motor) for controlling the liquid suction device 130 to move along the vertical direction (i.e., the direction away from or towards to the platform 110) with respect to the platform 110. By setting of the precise driving element, the adjustment of the up and down position of the liquid suction device 130 can be accurately controlled. Preferably, the coordinate measuring mechanism can be used to record the position and speed of the liquid suction device 130 in the vertical direction. The cleaning apparatus 1 also includes a load cell 170. One end of the load cell 170 is in contact with the liquid suction device 130 to detect the pressure value that the liquid suction device 130 applies on the chip stacked structure 2 when the first vertical lifting mechanism 181 controls the vertical suction mechanism 130 to vertically descend. In addition, the second vertical lifting mechanism 182 has a connection member and a precise driving element connected to the liquid supply device 120.

As shown in FIG. 2, the horizontal moving mechanism 183 is disposed above the platform 110 and is respectively connected with the liquid supply device 120 and the liquid suction device 130 for controlling the horizontal movement of the liquid supply device and the liquid suction device. For example, the horizontal moving mechanism 183 may use an X-Y table to precisely control the horizontal movement of the liquid supply device 120 and the liquid suction device 130 so as to accurately align to a cleaning position. In addition, the X-Y table can be used with point recording device that record moving positions of the liquid supply device 120 and the liquid suction device 130, so as to facilitate quick searching for positioning points of the liquid-supply device 120 and the liquid suction device 130 required for the chip stacked structure 2 of the same pattern in mass production.

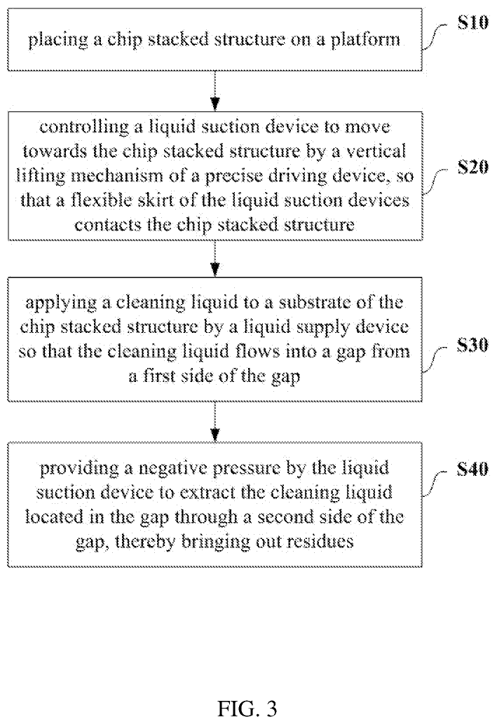

Referring to FIG. 3, which shows a flow chart of a cleaning method according to a preferred embodiment of the present disclosure. The cleaning method of the present disclosure can be performed by the cleaning apparatus 1 described above. The cleaning method includes the following steps. Firstly, step S10 is performed to place the chip stacked structure 2 on the platform 110. After the chip stacked structure 2 is placed thereon, the horizontal moving mechanism 183 controls the horizontal movement of the liquid supply device 120 and the liquid suction device 130 over the platform 110 to align the liquid supply device 120 with the first side P1 of the gap G, and align the liquid suction device 130 with the second side P2 of the gap G.

In step S20, the first vertical lifting mechanism 181 controls the liquid suction device 130 to move toward the chip stacked structure 2, so that the flexible skirt 132 of the liquid suction device 130 is in contact with the chip stacked structure 2. Preferably, while the first vertical lifting mechanism 181 controls the vertically descend of the liquid suction device 130, the pressure value of the liquid suction device 130 applied to the chip stacked structure 2 can be detected by the load cell 170, so that the problem of chip C damage caused by excessive pressure can be avoided.

In step S30, the liquid supply device 120 applies the cleaning liquid to the substrate S of the chip stacked structure 2, so that the cleaning liquid flows into the gap G from the first side P1 of the gap G.

Finally, step S40 is performed to provide a negative pressure by the liquid suction device 130 to extract the cleaning liquid located in the gap G via the second side P2 of the gap G, and bring out the residues R together. It can be understood that while providing the negative pressure by the liquid suction device 130, the negative pressure sensor 151 detects the negative pressure value between the liquid suction device 130 and the chip stacked structure 2 when the flexible skirt 132 of the liquid suction device 130 is in contact with the chip stacked structure 2. On the other hand, after the liquid suction device 130 provides the negative pressure to extract the cleaning liquid, gas, and residues R, the cleaning liquid and the gas extracted through the suction outlet 131 of the liquid suction device 130 may be separated by the gas-liquid separation device 160.

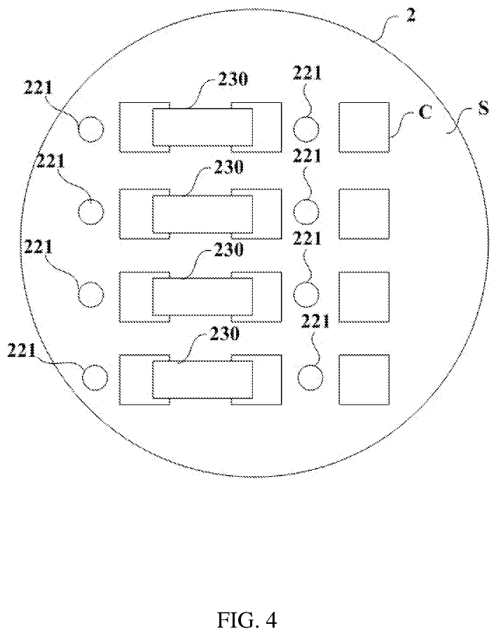

Referring to FIG. 4, which shows a schematic diagram of a cleaning apparatus according to a second preferred embodiment of the present disclosure. The cleaning apparatus of the second preferred embodiment is substantially the same as the cleaning apparatus 1 of the first preferred embodiment. The difference is that the cleaning apparatus of the second preferred embodiment includes a plurality of liquid supply devices and a plurality of liquid suction devices 230. In this way, a plurality of gaps G between the chips C and the substrate S of the chip stacked structure 2 can be cleaned at one time. Specifically, the plurality of liquid suction devices 230 are aligned in a row, and each liquid suction device 230 spans two adjacent chips C. In addition, two opposite sides of the two adjacent chips C are provided with a pair of liquid outlets 221 of the liquid supply device so that each liquid suction device 230 can be used to clean the gap G between two adjacent chips C and the substrate S. That is, the gap G between 2N chips C and the substrate S can be cleaned at one time by the arrangement of the N rows of liquid supply devices and the liquid suction devices 230. Therefore, the cleaning time of the chip stacked structure 2 can be effectively shortened to improve the cleaning performance.

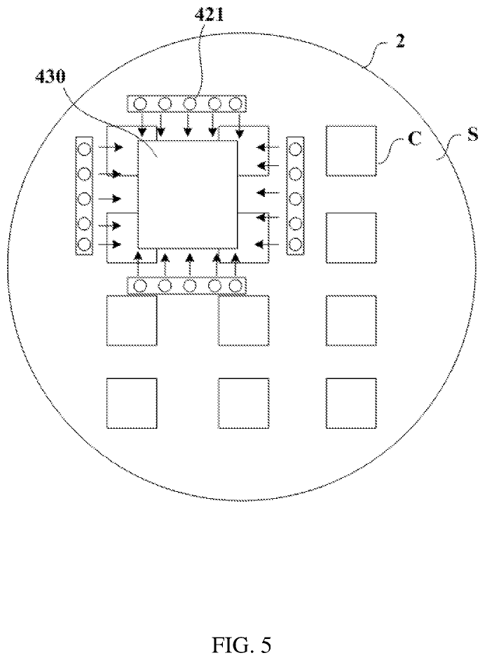

Referring to FIG. 5, which shows a schematic diagram of a cleaning apparatus according to a third preferred embodiment of the present disclosure. The cleaning apparatus of the third preferred embodiment is substantially the same as the cleaning apparatus 1 of the first preferred embodiment. The difference is that the cleaning apparatus of the third preferred embodiment employs the liquid suction device 430 to be moved for placing across four chips C. The liquid supply device is provided with four rows of liquid outlets 421, and the liquid supply device is moved to align the four rows of liquid outlets 421 with a position where across four chip C. The liquid supply device is provided with four rows of liquid outlets 421, and the liquid supply device is moved to align the four rows of liquid outlets 421 at four opposing outer edges of the four chips C. Therefore, during each cleaning process, the gap G between the four chips C and the substrate S on the chip stacked structure 2 can be cleaned, so that the cleaning time of the chip stacked structure 2 can be effectively shortened to improve the cleaning performance.

As described above, the present disclosure provides a vertical lifting mechanism in the cleaning apparatus to accurately control a relative position between the liquid suction device and the chip stacked structure, so that it can avoid the problem caused from the liquid suction device applies an improper downforce on the chip stacked structure, thereby causing chips damage. Moreover, by providing a flexible skirt at the bottom of the liquid suction device, the flexible skirt can contact with the chip stacked structure and circumferentially cover a range of chip stacked structures to avoid leakage of gas or liquid.

The above descriptions are merely preferable embodiments of the present disclosure, and are not intended to limit the scope of the present disclosure. Any modification or replacement made by those skilled in the art without departing from the spirit and principle of the present disclosure should fall within the protection scope of the present disclosure. Therefore, the protection scope of the present disclosure is subject to the appended claims.

What is claimed is:

1. A cleaning apparatus for removing residues from a chip stacked structure, the chip stacked structure comprising a substrate and a plurality of chips, the chips being separated from the substrate by a gap, and the residues located in the gap between the chips and the substrate, the cleaning apparatus comprising:
a platform for placing the chip stacked structure thereon;
a liquid supply device for applying a cleaning liquid to the substrate of the chip stacked structure so that the cleaning liquid flows into the gap from a first side of the gap; and
a liquid suction device for providing a negative pressure to extract the cleaning liquid located in the gap through a second side of the gap, thereby bringing out the residues, wherein the liquid suction device comprising:
a suction outlet; and
a flexible skirt circumferentially disposed around the suction outlet and configured for contacting the chip stacked structure and blocking the cleaning liquid and gas therein from escaping through the second side of the gap so that the cleaning liquid and the gas will be ensured to be extracted through the suction outlet.

2. The cleaning apparatus as claimed in claim 1, wherein a material of the flexible skirt comprises a polyvinyl alcohol sponge.

3. The cleaning apparatus as claimed in claim 1, further comprising a precise driving device used for controlling the liquid suction device to move along a vertical direction and a horizontal direction with respect to the platform.

4. The cleaning apparatus as claimed in claim 3, wherein the precise driving device comprises a vertical lifting mechanism for controlling the liquid suction device to move along the vertical direction with respect to the platform, and the vertical lifting mechanism comprises a stepper motor.

5. The cleaning apparatus as claimed in claim 3, wherein the precise driving device comprises a horizontal moving mechanism for controlling the liquid suction device to move along the horizontal direction with respect to the platform, and the horizontal moving mechanism comprises an X-Y table.

6. The cleaning apparatus as claimed in claim 5, wherein the horizontal moving mechanism can also be used to control a horizontal movement of the liquid supply device.

7. The cleaning apparatus as claimed in claim 1, further comprising a load cell, one end of the load cell contacts to the liquid suction device to detect a pressure value of the liquid suction device applied to the chip stacked structure.

8. The cleaning apparatus as claimed in claim 1, further comprising a gas-liquid separation device connected to the liquid suction device for separating the cleaning liquid and the gas which are extracted through the suction outlet.

9. The cleaning apparatus as claimed in claim 1, further comprising a negative pressure sensor connected to the liquid suction device for detecting a negative pressure value between the liquid suction device and the chip stacked structure when the flexible skirt of the liquid suction device contacts the chip stacked structure.

10. A cleaning apparatus for removing residues from a chip stacked structure, the chip stacked structure comprising a substrate and a plurality of chips, the chips being separated from the substrate by a gap, and the residues located in the gap between the chips and the substrate, the cleaning apparatus comprising:
a platform for placing the chip stacked structure thereon;
a liquid supply device for applying a cleaning liquid to the substrate of the chip stacked structure so that the cleaning liquid flows into the gap from a first side of the gap;
a liquid suction device for providing a negative pressure to extract the cleaning liquid located in the gap through a second side of the gap, thereby bringing out the residues; and
a precise driving device for controlling the liquid suction device to move along a vertical direction and a horizontal direction with respect to the platform, wherein the precise driving device comprising:
a vertical lifting mechanism for controlling the liquid suction device to move along the vertical direction with respect to the platform, and the vertical lifting mechanism comprises a stepper motor; and
a horizontal moving mechanism for controlling the liquid suction device to move along the horizontal direction with respect to the platform, and the horizontal moving mechanism comprises an X-Y table.

11. The cleaning apparatus as claimed in claim 10, wherein the horizontal moving mechanism can also be used to control a horizontal movement of the liquid supply device.

12. The cleaning apparatus as claimed in claim 10, wherein the liquid suction device comprises:
a suction outlet; and
a flexible skirt circumferentially disposed around the suction outlet and configured for contacting the chip stacked structure and blocking the cleaning liquid and gas therein from escaping through the second side of the gap so that the cleaning liquid and the gas will be ensured to be extracted through the suction outlet.

13. The cleaning apparatus as claimed in claim 12, wherein a material of the flexible skirt comprises a polyvinyl alcohol sponge.

14. The cleaning apparatus as claimed in claim 12, further comprising a negative pressure sensor connected to the liquid suction device for detecting a negative pressure value between the liquid suction device and the chip stacked structure when the flexible skirt of the liquid suction device contacts the chip stacked structure.

15. The cleaning apparatus as claimed in claim 10, further comprising a load cell, one end of the load cell contacts to the liquid suction device to detect a pressure value of the liquid suction device applied to the chip stacked structure.

16. The cleaning apparatus as claimed in claim 10, further comprising a gas-liquid separation device connected to the liquid suction device for separating the cleaning liquid and the gas which are extracted through the suction outlet.

17. A cleaning method, performed by a cleaning apparatus which comprises a platform, a liquid supply device, a liquid suction device, and a precise driving device, and the cleaning method used for removing residues from a chip stacked structure, the chip stacked structure comprising a substrate and a plurality of chips, the chips being separated from the substrate by a gap, and the residues located in the gap between the chips and the substrate, the cleaning method comprising:
placing the chip stacked structure on the platform;
controlling the liquid suction device to move towards the chip stacked structure by a vertical lifting mechanism of the precise driving device, so that a flexible skirt of the liquid suction devices contacts the chip stacked structure;
applying the cleaning liquid to the substrate of the chip stacked structure by the liquid supply device so that the cleaning liquid flows into the gap from a first side of the gap; and
providing a negative pressure by the liquid suction device to extract the cleaning liquid located in the gap through a second side of the gap, thereby bringing out the residues.

18. The cleaning method as claimed in claim 17, after the liquid suction device is controlled to move towards the chip stacked structure by the precise driving device, further comprising: detecting a pressure value of the liquid suction device applied to the chip stacked structure by a load cell.

19. The cleaning method as claimed in claim 17, when a negative pressure is provided by the liquid suction device, further comprising: detecting a negative pressure value between the liquid suction device and the chip stacked structure by a negative pressure sensor when the flexible skirt of the liquid suction device contacts the chip stacked structure.

20. The cleaning method as claimed in claim 17, after the chip stacked structure is placed on the platform, further comprising: controlling a horizontal movement of the liquid supply device and the liquid suction device over the platform by a horizontal moving mechanism of a precise driving device to align the liquid supply device with the first side of the gap and align the liquid suction device with the second side of the gap.

21. The cleaning method as claimed in claim 17, after the negative pressure is provided by the liquid suction device to extract the cleaning liquid, the gas, and the residues, further comprising: separating the cleaning liquid and the gas which are extracted through the suction outlet by a gas-liquid separation device.

22. The cleaning method as claimed in claim 17, wherein a material of the flexible skirt of the liquid suction device comprises a polyvinyl alcohol sponge.
